(19) United States
(12) Patent Application Publication
(10) Pub. No.: US 2017/0242299 A1
(43) Pub. Date: Aug. 24, 2017

(54) LIQUID CRYSTAL DISPLAY PANEL AND MOBILE PHONE

(71) Applicant: Wuhan China Star Optoelectronics Technology Co., Ltd., Wuhan (CN)

(72) Inventors: Hongqing CUI, Shenzhen (CN); Wenqing SONG, Shenzhen (CN)

(73) Assignee: Wuhan China Star Optoelectronics Technology Co., Ltd., Wuhan (CN)

(21) Appl. No.: 15/176,327

(22) Filed: Jun. 8, 2016

(30) Foreign Application Priority Data
Feb. 23, 2016 (CN) 2016100987421

(51) Int. Cl. G02F 1/1335; G02F 1/1333; H04B 1/3827; G02F 1/1343; H01L 29/786; H01L 27/12; G02F 1/1362; G02F 1/1368

(52) U.S. Cl. CPC G02F 1/133553; G02F 1/133602; G02F 1/136209; G02F 1/133345; G02F 1/1368; G02F 1/136227; G02F 1/13439; G02F 1/133514; H01L 29/78675; H01L 29/78621; H01L 29/78633; H01L 27/1222; H01L 27/124; H04B 1/3833; G02F 2001/133616; G02F 2001/133302; G02F 2202/104; G02F 2202/06

(57) ABSTRACT

A liquid crystal display panel and a mobile phone. The liquid crystal display panel includes a first screen and a second screen which are disposed adjacently, the two screens are controlled by independent light strips, the light strips are both disposed in a backlight module, wherein, the second screen includes an array substrate and a color filter substrate, the array substrate includes multiple reflective electrodes disposed separately. Accordingly, the second screen of the liquid crystal panel of the present invention can reflect an external environment light to decrease the dependence on the backlight source such that the power consumption can be saved.

### BACKGROUND OF THE INVENTION

1. Field of the Invention

The present invention relates to a flat display technology field, and more particularly to a liquid crystal display panel and a mobile phone.

2. Description of Related Art

Along with popularization the smart phone, the requirement for the smart phone is higher and higher by the people. The current smart phone launches a dual screen display function. That is, when a main screen is turned on, an assistant screen can display a shortcut of various applications such as music playing control. When the main screen is turned off, the assistant screen is maintained to be normally turned on to display time, date, weather, power and so on. However, the current phone having the dual screen display function depends on a backlight source too much. Besides, the assistant screen which is normally turned on will consume a portion of power such that the power consumption of the mobile phone is too high.

### SUMMARY OF THE INVENTION

Accordingly, the present invention provides a liquid crystal display panel and a mobile phone. Through disposing reflective electrodes at the assistant screen in order to use an external environment light to be reflected to display a simple image, to save the power consumption.

One aspect of the present invention provides a liquid crystal display panel, comprising: a first screen; a second screen; wherein, the first screen and the second screen are disposed adjacently, an area of the second screen is less than an area of the first screen, the first screen is provided with a first light strip, the second screen is provided with a second light strip, the first light strip and the second light strip are both disposed in a backlight module, the second screen includes an array substrate and a color filter substrate, the array substrate includes multiple reflective electrodes disposed separately.

Wherein, the second screen further includes liquid crystals disposed between the array substrate and the color filter substrate, the second light strip is disposed at a side of the second screen such that when an external environment light is incident to the second screen, the light is reflected by the reflective electrode in order to display an image by the second screen.

Wherein, the backlight module is disposed below the first screen and the second screen.

Wherein, the array substrate includes a glass substrate, a light-shielding layer, a first insulation layer, an active layer, a gate electrode, a second insulation layer, a source electrode, a drain electrode, a third insulation layer and a reflective electrode, wherein,

the light-shielding layer is disposed on the glass substrate;

the first insulation layer covers the light-shielding layer and is extended on the glass substrate;

the active layer is disposed on the first insulation layer and corresponding to a position of the light-shielding layer;

the gate electrode is disposed above the active layer;

the second insulation layer covers the gate electrode and is extended on the active layer and the first insulation layer, besides, the second insulation layer is provided with a first through hole and a second through hole, the source electrode and the drain electrode are connected with the active layer respectively through the first through hole and the second through hole; and

the third insulation layer is disposed on the source electrode and the drain electrode and is extended on the second insulation layer, the third insulation layer is provided with a third through hole, and the reflective electrode is connected with the source electrode through the third through hole.

Wherein, the active layer includes a low-temperature polysilicon, a light-doping region and an N+ heavy-doping region; the light-doping region is respectively located at two sides of the low-temperature polysilicon; the N+ heavy-doping region is respectively located at two sides of the light-doping region.

Wherein, the reflective electrode is an aluminum electrode.

Wherein, an integral surface of the color filter substrate is provided with a common electrode.

Wherein, a size of the first screen is 5.5 inch, and a size of the second screen is 2.3 inch.

Wherein, a PPI of the first screen is 534, a PPI of the second screen is 172.

Another aspect of the present invention provides a mobile phone, including a liquid crystal panel describe above.

Through above solutions, the beneficial effects of the present invention is: comparing to the conventional art, the mobile phone of the present invention includes a liquid crystal display panel, wherein, the liquid crystal display panel includes a first screen and a second screen which are disposed adjacently, the two screens are controlled by independent light strips, the light strips are both disposed in a backlight module, wherein, the second screen includes an array substrate and a color filter substrate, the array substrate includes multiple reflective electrodes disposed separately. Accordingly, the second screen of the liquid crystal panel of the present invention can reflect an external environment light to decrease the dependence on the backlight source such that the power consumption can be saved.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures. Wherein:

FIG. 1 is a schematic structure diagram of a liquid crystal display panel according to an embodiment of the present invention; and

FIG. 2 is a schematic structure diagram of an array substrate of the liquid crystal display panel shown in FIG. 1.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

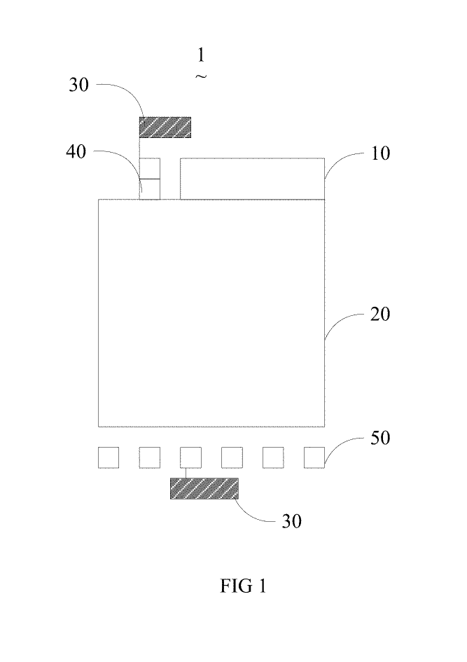

With reference to FIG. 1, and FIG. 1 is a schematic structure diagram of a liquid crystal display panel according to an embodiment of the present invention. As shown in FIG. 1, a liquid crystal display panel of the present embodiment includes a first screen 20 and a second screen 10 which are disposed adjacently. The first screen 20 is a main screen, the second screen 10 is an assistant screen. An area of the second screen 10 is less than an area of the first screen 20.

Wherein, the first screen 20 and the second screen 10 are respectively controlled by independent light strips. Each light strip is not limited to an LED. The first screen 20 is provided with a firs light strip 50, and the second screen 10 is provides with a second light strip 40. Preferably, the number of the first light strip 50 is multiple, and the number of the second light strip 40 is two. In the present embodiment, the first light strip 50 and the second light strip 40 are all disposed in a same backlight module 30. Besides, the first light strip 50 is disposed at a bottom of the first screen 20, and the second light strip 40 is disposed at a side of the second screen 10. Therefore, the backlight module 30 is extended at a bottom of the second screen 10. That is, the backlight module 30 is disposed at bottoms the first screen 20 and the second screen 10.

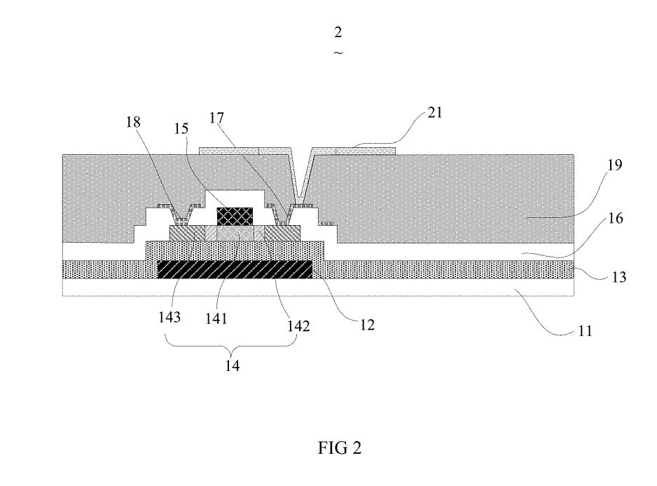

In the present, the second screen 10 is a reflective type liquid crystal screen, including an array substrate, a color filter substrate and liquid crystals disposed between the array substrate and the color filter substrate. Above the array substrate, multiple reflective electrodes 21 are separately disposed. With further reference to FIG. 2, and FIG. 2 is a schematic structure diagram of an array substrate of the liquid crystal display panel shown in FIG. 1

As shown in FIG. 2, the array substrate 2 includes a glass substrate 11, a light-shielding layer 12, a first insulation layer 13, an active layer 14, a gate electrode 15, a second insulation layer 16, a source electrode 17, a drain electrode 18, a third insulation layer 19 and a reflective electrode 21. Wherein, the light-shielding layer 12 is disposed on the glass substrate 11, the first insulation layer 13 covers the light-shielding layer 12 and is extended on the glass substrate 11, the active layer 14 is disposed on the first insulation layer 13 and corresponding to a position of the light-shielding layer 12, the gate electrode 15 is disposed above the active layer 14, the second insulation layer 16 covers the gate electrode 15 and is extended on the active layer 14 and the first insulation layer 13. Besides, the second insulation layer 16 is provided with a first through hole and a second through hole. The source electrode 17 and the drain electrode 18 are connected with the active layer 14 respectively through the first through hole and the second through hole.

The third insulation layer 19 is disposed on the source electrode 17 and the drain electrode 18 and is extended on the second insulation layer 16. The third insulation layer 19 is provided with a third through hole. The reflective electrode 21 is connected with the source electrode 17 through the third through hole. Wherein, the light-shielding layer 12 is also called as a black matrix (BM) layer, and can prevent a background light from leaking in order to increase a display contrast ratio, prevent a color mixing and increase the color purity.

The active layer adopts a channel design, including a low-temperature polysilicon 141, a light-doping region 142 and an N+ heavy-doping region 143. Wherein, a position of the low-temperature polysilicon 141 is corresponding to a position of the gate electrode 15. The light-doping region 142 is respectively located at two sides of the low-temperature polysilicon 141, the N+ heavy-doping region 143 is respectively located at two sides of the light-doping region 142. That is, the N+ heavy-doping region 143 is separated from the low-temperature polysilicon 141 by the light-doping region 142. Wherein, the source electrode 17 and the drain electrode 18 are respectively connected to the N+ heavy-doping region 143 through the first through hole and the second through hole. The second insulation layer 16 and the third insulation layer 19 are also called as a passivation layer. Wherein, the third insulation layer 19 is an organic insulation layer.

Wherein, the reflective electrode 21 adopts an aluminum (Al) electrode. Using the aluminum electrode as the reflective electrode 21, the reflectivity is higher than a normal electrode about 53.1%. Besides, aluminum can decrease absorption of light of an electrode. Because the reflective electrode 21 is located at the uppermost of the array substrate 2, through reflecting an external environment light to decrease the dependence on the backlight source such that the power consumption of the array substrate 2 can be decreased. In another embodiment, silicon dioxide (SiO2) and an Al reflector are superposed to manufacture the reflective electrode 21. Because the second screen 10 is provided with the reflective electrode 21, when an external environment light is incident to the second screen 10, the external environment light can be reflected by the reflective electrode 21 so that the second screen 10 can display an image in order to save the power consumption of the liquid crystal display panel 1. That is, the second screen 10 has a static display function and a dynamic display function. In the static display function, the gate electrode 15 does not require to refresh row by row, and displaying a simple image under the external environment light such as time, information and so on to save the power consumption. In a dark environment, turning on the light strip in the backlight module 30 of the assistant screen, a simple image can be displayed to save power consumption.

In the present embodiment, a pixel circuit of the liquid crystal display panel 1 utilizes a design of MIP and area-dividing method to display 64 colors. Wherein, MIP is an abbreviation of Memory in pixel, and also known as pixel embedded storage design. A static display and a dynamic display are existed when operating. When under the static display, does not require the Gate (gate electrode 15) to refresh, the power consumption is 1/10 of the dynamic display. An image displayed by the dynamic display is like a normal display. Wherein, the operation principle of the area-dividing method is:

Using a 2bit SRAM image information written in a sub-pixel, and in each region of the sub-pixel divided into three portions, performing a white or a black display in order to achieve a 4-grayscales performance ability. Here, dividing the sub-pixels into three portions means dividing the 2bit information into three portions to display in the sub-pixel. Upper and lower regions are assigned to a high level display, and a middle region is assigned to a low level display such that the center of weight is always located at the middle region. Through the 4-grayscales performance, the center of the weight of each bit is equal to prevent the incongruity when displaying. Therefore, through 4-grayscales performance of RGB colors to display 64 colors, and through MIP design, the power consumption can be decreased to 1/10, and does not require the gate electrode 15 to scan row by row, a static image can be displayed.

In the present embodiment, an integral surface of the color filter substrate of the second screen 10 is provided with a common electrode.

Besides, the first screen 20 is a transmissive type liquid crystal screen, adopting a normal structure of a conventional LCD, no more repeating.

Wherein, the screen size, the resolution, the pixel size and PPI (Pixels Per Inch) of the first screen 20 and the second screen 10 of the present embodiment can refer to the following table 1:

| | Screen size | Resolution | | Pixel size | | PPI |
|---|---|---|---|---|---|---|
| Main screen | 5.5 | 2560 | 1440 | 15.85 | 47.56 | 534 |
| Assistant | 2.3 | 392 | 50 | 49.28 | 147.83 | 172 |
| screen | | | | | | |

Preferably, a size of the first screen 20 is 5.5 inch, a size of the second screen 10 is 2.3 inch, a PPI of the first screen 20 is 534, and a PPI of the second screen 10 is 172.

Therefore, the liquid crystal display panel 1 of the present embodiment includes a main screen and an assistant screen, which can increase a screen to body ratio. Besides, the main screen and the assistant screen are controlled respectively, the assistant screen adopts a reflective type technology, the reflective electrode 21 is disposed at the uppermost of the array substrate 2 in order to reflect an external environment light, decrease the dependence on the backlight source, and decrease the power consumption.

The present invention also discloses a mobile phone, the mobile phone includes the above liquid crystal display panel 1.

In summary, comparing to the conventional art, the liquid crystal display panel 1 of the present invention includes a first screen 20 and a second screen 10 which are disposed adjacently, the two screens are controlled by independent light strips, the light strips are both disposed in a backlight module 30, wherein, the second screen 10 includes an array substrate and a color filter substrate, the array substrate includes multiple reflective electrodes 21 disposed separately. Accordingly, the second screen 10 of the liquid crystal display panel 1 of the present invention can reflect an external environment light to decrease the dependence on the backlight source such that the power consumption can be saved.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A liquid crystal display panel, comprising:
a first screen;
a second screen;
wherein, the first screen and the second screen are disposed adjacently, an area of the second screen is less than an area of the first screen, the first screen is provided with a first light strip, the second screen is provided with a second light strip, the first light strip and the second light strip are both disposed in a backlight module, the second screen includes an array substrate and a color filter substrate, the array substrate includes multiple reflective electrodes disposed separately.

2. The liquid crystal display panel according to claim 1, wherein, the second screen further includes liquid crystals disposed between the array substrate and the color filter substrate, the second light strip is disposed at a side of the second screen such that when an external environment light is incident to the second screen, the light is reflected by the reflective electrode in order to display an image by the second screen.

3. The liquid crystal display panel according to claim 2, wherein, the backlight module is disposed below the first screen and the second screen.

4. The liquid crystal display panel according to claim 1, wherein, the array substrate includes a glass substrate, a light-shielding layer, a first insulation layer, an active layer, a gate electrode, a second insulation layer, a source electrode, a drain electrode, a third insulation layer and a reflective electrode, wherein,
the light-shielding layer is disposed on the glass substrate;
the first insulation layer covers the light-shielding layer and is extended on the glass substrate;
the active layer is disposed on the first insulation layer and corresponding to a position of the light-shielding layer;
the gate electrode is disposed above the active layer;
the second insulation layer covers the gate electrode and is extended on the active layer and the first insulation layer, besides, the second insulation layer is provided with a first through hole and a second through hole, the source electrode and the drain electrode are connected with the active layer respectively through the first through hole and the second through hole; and
the third insulation layer is disposed on the source electrode and the drain electrode and is extended on the second insulation layer, the third insulation layer is provided with a third through hole, and the reflective electrode is connected with the source electrode through the third through hole.

5. The liquid crystal display panel according to claim 4, wherein, the active layer includes a low-temperature polysilicon, a light-doping region and a N+ heavy-doping region; the light-doping region is respectively located at two sides of the low-temperature polysilicon; the N+ heavy-doping region is respectively located at two sides of the light-doping region.

6. The liquid crystal display panel according to claim 1, wherein, the reflective electrode is an aluminum electrode.

7. The liquid crystal display panel according to claim 1, wherein, an integral surface of the color filter substrate is provided with a common electrode.

8. The liquid crystal display panel according to claim 1, wherein, a size of the first screen is 5.5 inch, and a size of the second screen is 2.3 inch.

9. The liquid crystal display panel according to claim 8, wherein, a PPI of the first screen is 534, a PPI of the second screen is 172.

10. A mobile phone, wherein, the mobile phone includes the liquid crystal display panel as claimed in claim 1.
